(19) United States
(12) Patent Application Publication
(10) Pub. No.: US 2025/0056765 A1
(43) Pub. Date: Feb. 13, 2025

(54) COOLING DEVICE AND COOLING SYSTEM

(71) Applicant: Fujitsu Limited, Kawasaki-shi (JP)

(72) Inventors: Hideo Kubo, Kawasaki (JP); Toru Kobayashi, Kawasaki (JP); Nobumitsu Aoki, Kawasaki (JP); Kenji Sasabe, Kawasaki (JP); Keita Hirai, Kawasaki (JP); Hiromasa Miyata, Sumida (JP); Hideto Fukushima, Kawasaki (JP); Masahide Kodama, Kawasaki (JP); Atsushi Endo, Kawasaki (JP); Takashi Urai, Kawasaki (JP)

(73) Assignee: Fujitsu Limited, Kawasaki-shi (JP)

(21) Appl. No.: 18/782,464

(22) Filed: Jul. 24, 2024

(30) Foreign Application Priority Data
Aug. 7, 2023 (JP) 2023-128866

(51) Int. Cl. H05K 7/20

(52) U.S. Cl. CPC H05K 7/20336; H05K 7/20154; H05K 7/20318; H05K 7/20327; H05K 7/20418

(57) ABSTRACT

A cooling device includes a container, a heat receiver to receive heat from a cooling target and evaporate a refrigerant inside the container, a condenser disposed away from the heat receiver, and to condense the gas-phase refrigerant, a liquid transporter to couple the condenser and the heat receiver, and transport the liquid-phase refrigerant to the heat receiver from the condenser, a first transporter to couple the heat receiver and the condenser, and include a first transport-space inside the first transporter, in which the gas-phase refrigerant is transported to the condenser from the heat receiver, and a second transporter provided in pairs over two sides in a direction orthogonal to a moving-direction of the refrigerant in the first transporter, and to couple the heat receiver and the condenser, and include a second transport-space inside the second transporter, in which the gas-phase refrigerant is transported to the condenser from the heat receiver.

### CROSS-REFERENCE TO RELATED APPLICATION

This application is based upon and claims the benefit of priority of the prior Japanese Patent Application No. 2023-128866, filed on Aug. 7, 2023, the entire contents of which are incorporated herein by reference.

### FIELD

The embodiments discussed herein are related to a cooling device and a cooling system.

### BACKGROUND

There is a cooling system including a heat receiving unit, a heat radiating unit, and a connecting unit that connects the heat receiving unit and the heat radiating unit, in which a base portion in thermal contact with a cooling target object in the heat receiving unit includes a heat receiving unit outer wall portion that forms a part of an outer wall of the heat receiving unit, and a plurality of protruding portions disposed on a bottom surface of the heat receiving unit in contact with a refrigerant.

International Publication Pamphlet No. WO 2012/115214 is disclosed as related art.

### SUMMARY

According to an aspect of the embodiments, a cooling device includes a container in which a refrigerant is sealed, a heat receiver configured to receive heat from a cooling target and evaporate the refrigerant inside the container, a condenser that is disposed away from the heat receiver inside the container, and configured to condense the gas-phase refrigerant, a liquid transporter configured to couple the condenser and the heat receiver, and transport the liquid-phase refrigerant to the heat receiver from the condenser by a capillary phenomenon, a first transporter configured to couple the heat receiver and the condenser inside the container, and include a first transport space inside the first transporter, in which the gas-phase refrigerant is transported to the condenser from the heat receiver, and a second transporter that is provided in pairs over two sides in a direction orthogonal to a moving direction of the refrigerant in the first transporter inside the container, and configured to couple the heat receiver and the condenser, and include a second transport space inside the second transporter, in which the gas-phase refrigerant is transported to the condenser from the heat receiver.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view illustrating a cooling system of a first embodiment;

FIG. 2 is an exploded perspective view illustrating the cooling system of the first embodiment;

FIG. 3 is a partial plan view illustrating an electronic appliance including the cooling system of the first embodiment together with an internal structure of the cooling system;

FIG. 4 is a plan view illustrating the internal structure of the cooling system of the first embodiment;

FIG. 5 is a cross-sectional view taken along a line 5-5 in FIG. 4, illustrating the cooling system of the first embodiment in a non-inclined state;

FIG. 6 is a cross-sectional view illustrating the cooling system of the first embodiment in an inclined state;

FIG. 7 is a plan view illustrating one end portions of transport pipes in the cooling system of the first embodiment together with a part of an evaporation unit;

FIG. 8 is a cross-sectional view illustrating another end portion of the transport pipe in the cooling system of the first embodiment together with a part of a container;

FIG. 9 is a side view illustrating the one end portion of the transport pipe in the cooling system of the first embodiment together with a part of the evaporation unit;

FIG. 10 is a graph indicating a relationship between an inner diameter of the transport pipe and a height of a water column rising inside the transport pipe;

FIG. 11 is an enlarged cross-sectional view illustrating a state in which a refrigerant evaporates in the cooling system of the first embodiment at a portion denoted by reference sign 11 in FIG. 5;

FIG. 12 is an enlarged cross-sectional view illustrating a state in which the refrigerant condenses in the cooling system of the first embodiment at a portion denoted by reference sign 12 in FIG. 5;

FIG. 13A is a cross-sectional view taken along a line 13A-13A in FIG. 4, illustrating the cooling system of the first embodiment;

FIG. 13B is a cross-sectional view taken along a line 13B-13B in FIG. 4, illustrating the cooling system of the first embodiment;

FIG. 13C is a cross-sectional view taken along a line 13C-13C in FIG. 4, illustrating the cooling system of the first embodiment;

FIG. 14A is a perspective view illustrating flows of the refrigerant in the cooling system of the first embodiment;

FIG. 14B is a plan view illustrating flows of the refrigerant in the cooling system of the first embodiment;

FIG. 15A is a perspective view illustrating flows of a refrigerant in a cooling system of a comparative example;

FIG. 15B is a plan view illustrating flows of the refrigerant in the cooling system of the comparative example;

FIG. 16 is a plan view illustrating the internal structure of the cooling system of the present disclosure together with an injection hole and an injection pipe;

FIG. 17 is a cross-sectional view taken along a line 17-17 in FIG. 16, illustrating the internal structure of the cooling system of the present disclosure;

FIG. 18 is a cross-sectional view illustrating the injection pipe of the cooling system of the present disclosure in an unsealed state;

FIG. 19 is a cross-sectional view illustrating the injection pipe of the cooling system of the present disclosure in a compressed and sealed state;

FIG. 20 is a cross-sectional view illustrating the injection hole of the cooling system of the present disclosure in a sealed state with a plug at a tip of the injection pipe;

FIG. 21 is an enlarged perspective view illustrating a net member and a vicinity of the net member in a cooling system of a second embodiment;

FIG. 22 is a plan cross-sectional view partially illustrating a cooling system of a third embodiment; and

FIG. 23 is a cross-sectional view taken along a line 23-23 in FIG. 22, illustrating the cooling system of the third embodiment.

### DESCRIPTION OF EMBODIMENTS

There is a cooling system capable of continuously transporting heat received by a heat receiving unit to a part other than the heat receiving unit, by repeatedly performing vaporization and condensation of a refrigerant inside a container in which the refrigerant is sealed, and circulating the refrigerant. In the cooling system that circulates the refrigerant, the cooling target can be cooled by releasing the heat transported by the refrigerant to the outside.

In such cooling device and cooling system, when the circulation of the refrigerant is insufficient, heat may not be sufficiently transported by the vaporized refrigerant, and the cooling capacity may not be highly exhibited. In order to promote the circulation of the refrigerant, for example, it is conceivable to expand a space for transporting the gas-phase refrigerant to a condensation unit from the heat receiving unit. However, simply expanding a space for transporting the refrigerant involves a large space as a cooling device.

Hereinafter, embodiments of techniques capable to enhance cooling efficiency by promoting circulation of a refrigerant in a space-saving manner in a structure in which heat transfer is performed by a phase change between a gas phase and a liquid phase of the refrigerant in a container will be described.

### First Embodiment

A cooling device 40 and a cooling system 42 according to a first embodiment will be described in detail with reference to the drawings.

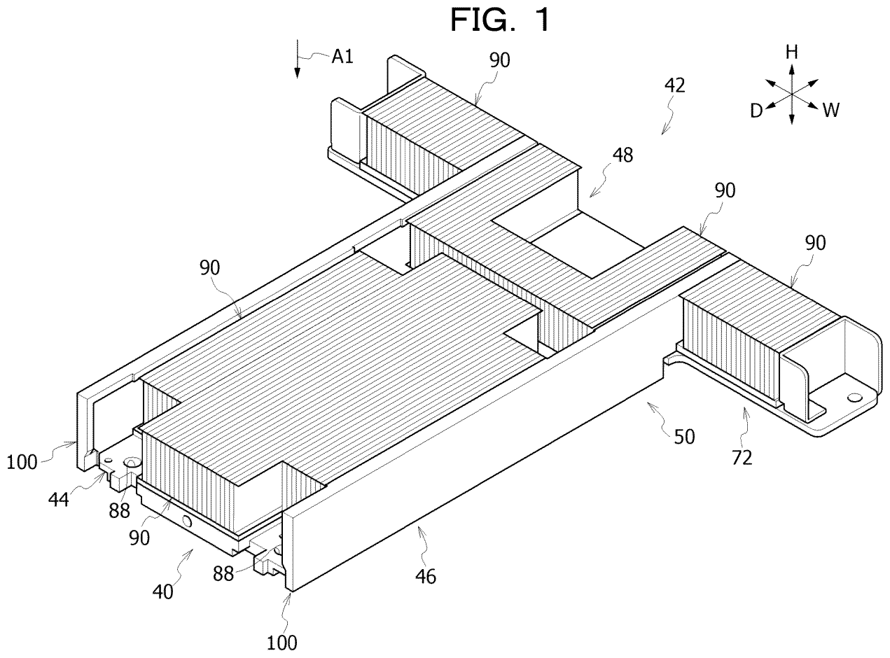

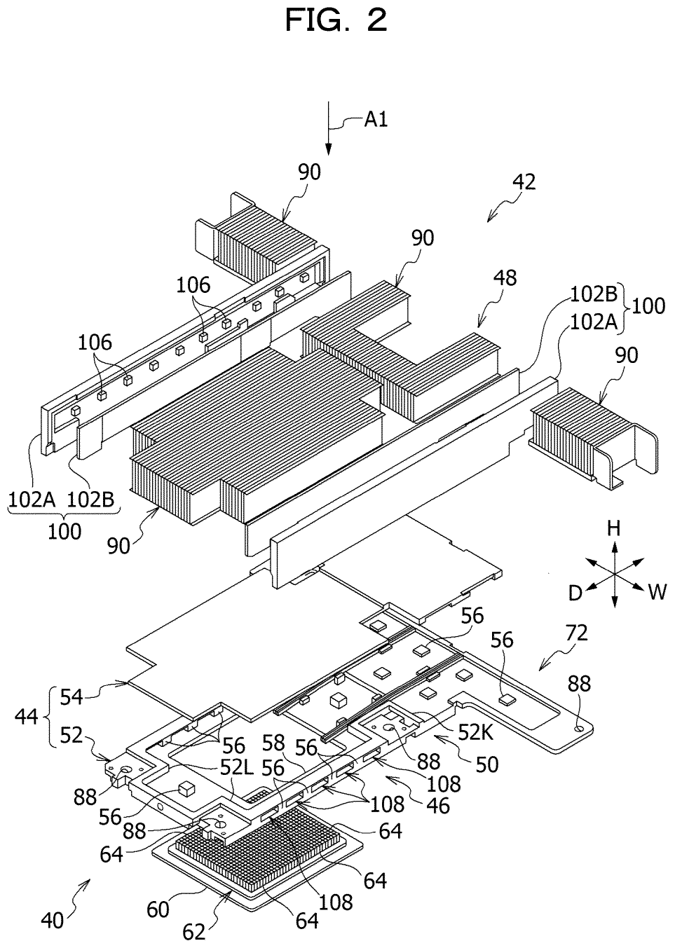

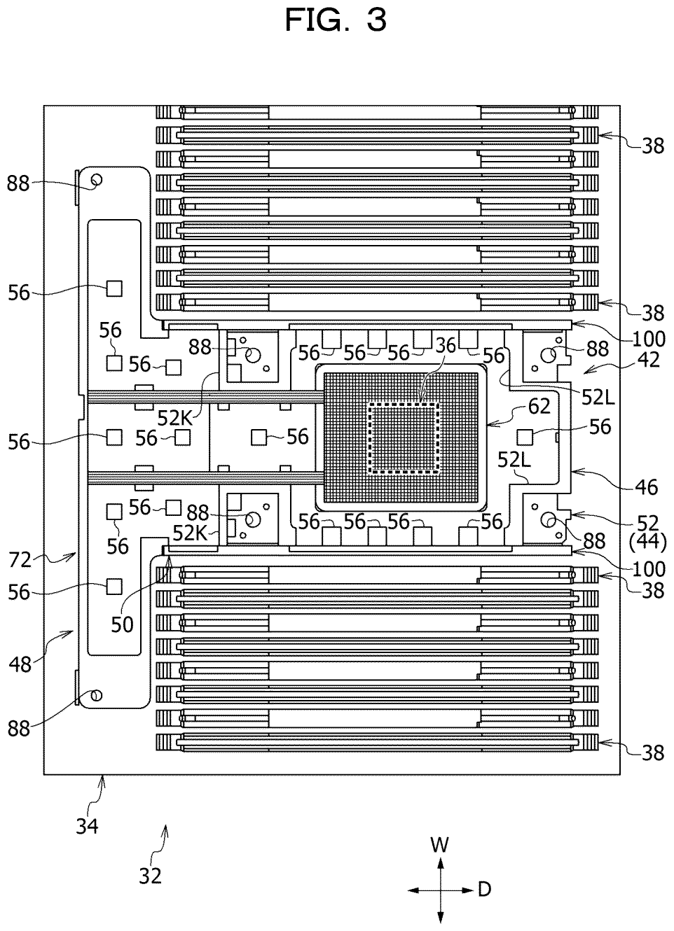

FIGS. 1 and 2 illustrate the cooling device 40 and the cooling system 42 of the first embodiment. In addition, FIG. 3 illustrates an electronic appliance 32 including the cooling system 42. Examples of the electronic appliance 32 include information communication appliances such as servers, but are not limited to this.

The electronic appliance 32 includes a substrate 34 having rigidity and an insulation property. A plurality of elements 36 and 38 is mounted on the substrate 34. The types of the elements 36 and 38 are not particularly limited, but in the example illustrated in FIG. 3, the element 36 is a processor chip and the elements 38 are memory chips. In this case, the element 36 is an example of a heating element. The cooling system 42 is disposed in contact with the element 36 and cools the element 36.

As illustrated in FIGS. 1 to 5, the cooling system 42 includes the cooling device 40. The cooling device 40 includes a container 44, a heat receiving unit (a heat receiver) 46, a heat radiating unit (a heat radiator) 48, a first transport unit (a first transporter) 50, and a condensation unit (a condenser) 72. The container 44 has a plate shape including the heat receiving unit 46, the first transport unit 50, and the condensation unit 72. In the drawings, a width direction, a depth direction, and a height direction of the container 44 are represented by arrows W, D, and H, respectively.

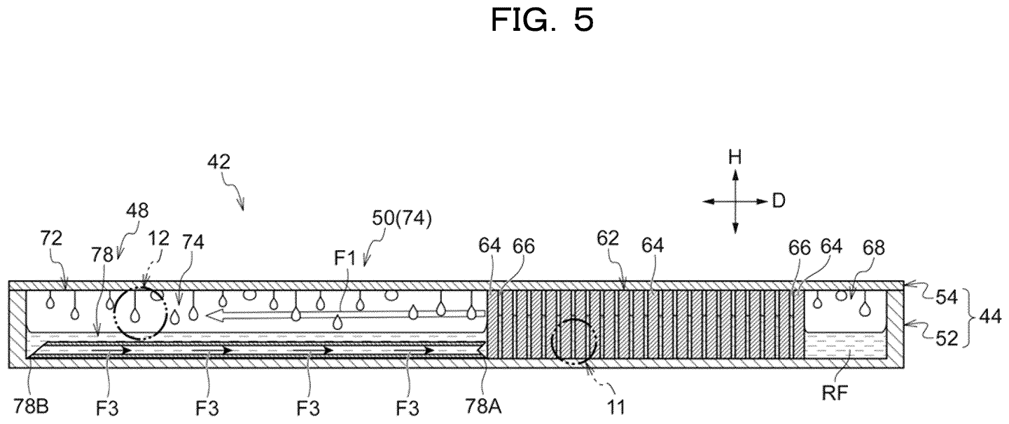

A refrigerant RF (see FIG. 5) is sealed inside the container 44. The type of the refrigerant RF is not limited as long as the refrigerant RF can transfer heat by circulating while performing a phase transition between a liquid phase and a gas phase in the container 44. As a specific example of the refrigerant RF, water can be used, and oil or alcohol, as well as water, can also be used. For example, water is easily available and also easy to handle, and water is used also in the present embodiment. The inside of the container 44 is maintained in a low pressure state, whereby the boiling point of the refrigerant is lowered. For example, when water is used as the refrigerant, by lowering the boiling point of the refrigerant, the temperature of the heat receiving unit 46 can be maintained at a temperature to an extent at which the element 36 stably operates.

The heat receiving unit 46 is a portion that is contacted the element 36 as illustrated in FIG. 3 and receives heat of the element 36. Then, the heat receiving unit 46 causes the heat received from the element 36 to act on the inside of the container 44. The heat receiving unit 46 includes an evaporation unit 62. The evaporation unit 62 vaporizes the liquid-phase refrigerant RF with heat inside the container 44.

The condensation unit 72 is disposed away from the heat receiving unit 46. In the condensation unit 72, heat of the gas-phase refrigerant RF is released, whereby this gas-phase refrigerant RF is condensed and liquefied.

The first transport unit 50 couples the heat receiving unit 46 and the condensation unit 72. The first transport unit 50 includes a first transport space 74 inside the first transport unit 50. As will be described later, in the first transport space 74, the gas-phase refrigerant RF and the liquid-phase refrigerant RF are transported between the evaporation unit 62 and the condensation unit 72. A part of heat of the refrigerant RF in a gas phase state is discharged to the outside also in the first transport unit 50, and the refrigerant RF is liquefied.

In the present embodiment, the condensation unit 72 has a shape wider in the width direction and shorter in the depth direction than the heat receiving unit 46. The first transport unit 50 is narrower in the width direction than the heat receiving unit 46 and has a depth for coupling the heat receiving unit 46 and the condensation unit 72.

As illustrated in FIG. 2, the container 44 has a structure in which two plate materials of a bottom plate 52 and a top plate 54 are fixed in a stacked state in a thickness direction (height direction).

The top plate 54 of the container 44 is provided with the heat radiating unit 48. The heat radiating unit 48 promotes an action of releasing heat of the refrigerant RF sealed in the container 44 to the outside.

The heat radiating unit 48 includes a plurality of fins 90. The fins 90 increase the substantial surface area of the container 44, for example, a heat radiation area for radiating heat to the outside (air cooling). For example, in the present embodiment, the fins 90 are installed in substantially an entire region of the top plate 54, and a wide heat radiation area is secured. For example, the fins 90 are formed in an upper-side region of the heat receiving unit 46, an upper-side region of the first transport unit 50, and an upper-side region of the condensation unit 72.

As will be described later, heat of the refrigerant RF is also released to the outside from a portion corresponding to the heat receiving unit 46 and a portion corresponding to the first transport unit 50. Therefore, in the container 44, a portion corresponding to the heat receiving unit 46 acts as a heat radiating portion, and furthermore, the heat radiating unit 48 acts as an additional heat radiating portion added to this heat radiating portion.

A fan is provided outside the cooling system 42. Wind generated by this fan hits the heat radiating unit 48, whereby heat radiation from the heat radiating unit 48 is promoted. The condensation unit 72 is disposed on an upstream side of the heat receiving unit 46 in the flow of wind from the fan. For example, the cooling device 40 is disposed to enable efficient cooling by causing wind from the fan to directly hit the fins 90 located in the condensation unit 72.

As illustrated in FIGS. 1 to 4, the bottom plate 52 is provided with insertion holes 88. A fastener such as a screw is inserted into the insertion hole 88 and fastened to the substrate 34. This ensures that the cooling system 42 is fixed to the substrate 34. Since the element 36 that is a cooling target is mounted on the substrate 34, the cooling system 42 is fixed also to the element 36.

As illustrated in FIGS. 2 to 4, standing walls 52K and 52L each having a shape surrounding the insertion hole 88 as viewed in the direction of arrow μl (illustrated in FIG. 2) are formed in the bottom plate 52. The standing wall 52K surrounds the insertion hole 88 at a central position in the depth direction, and the standing wall 52L surrounds the insertion hole 88L at a front position in the depth direction. The standing walls 52K and 52L isolate the insertion holes 88K and 88L from the space inside the container 44.

Note that, as illustrated in FIG. 2, the top plate 54 has a shape that avoids the insertion holes 88 when viewed in an overlapping direction (direction of arrow μl) with the bottom plate 52. Therefore, when the cooling system 42 is fixed to the substrate 34, a fastening operation (for example, an operation of turning a screw) may be performed on the fasteners without being disturbed by the top plate 54.

A plurality of second support columns 56 is erected from the bottom plate 52. Tips (upper ends) of the second support columns 56 are in contact with the top plate 54, and the top plate 54 is supported by the second support columns 56. The inside of the container 44 is maintained in a low pressure state, but even in the low pressure state, the second support columns 56 maintain an interval between the top plate 54 and the bottom plate 52. By maintaining the interval between the top plate 54 and the bottom plate 52, the internal volume of the container 44 is secured.

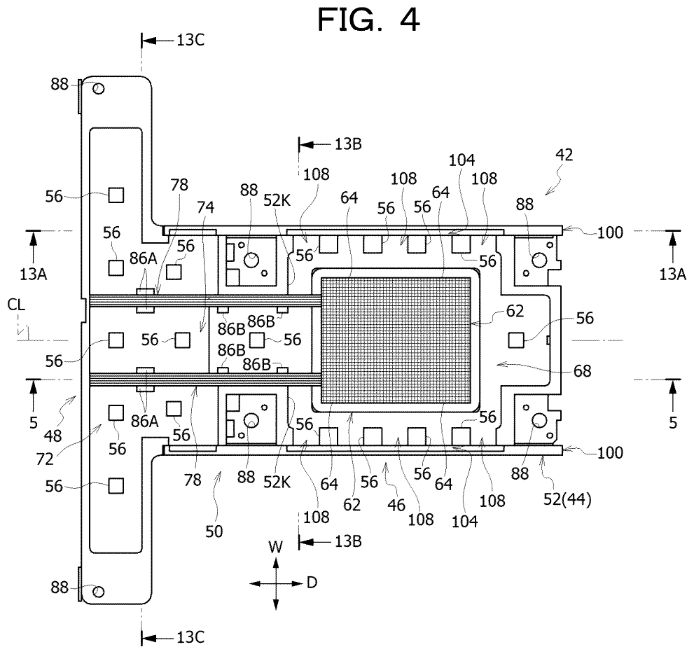

In the present embodiment, as illustrated in FIGS. 2 and 4, a plurality of the second support columns 56 is disposed in the heat radiating unit 48 with intervals interposed therebetween in the width direction of the container 44, and a plurality of the second support columns 56 is further disposed in the first transport unit 50 with intervals interposed therebetween in the depth direction of the container 44.

As illustrated in FIG. 2, in the bottom plate 52, an opening 58 is formed in a portion for the heat receiving unit 46. By fitting a heat receiving plate 60 into the opening 58, a sealed structure in the container 44 is achieved by the bottom plate 52, the top plate 54, and the heat receiving plate 60.

On the heat receiving plate 60, a plurality of column members 64 is erected toward the top plate 54. As illustrated in detail also in FIGS. 5 to 7, the plurality of column members 64 is disposed with regular intervals interposed therebetween in the width direction and the depth direction, and grid-like grooves 66 are formed between the column members 64. A groove width W1 of the groove 66 is narrower than an inner diameter N1 of a transport pipe 78 to be described later.

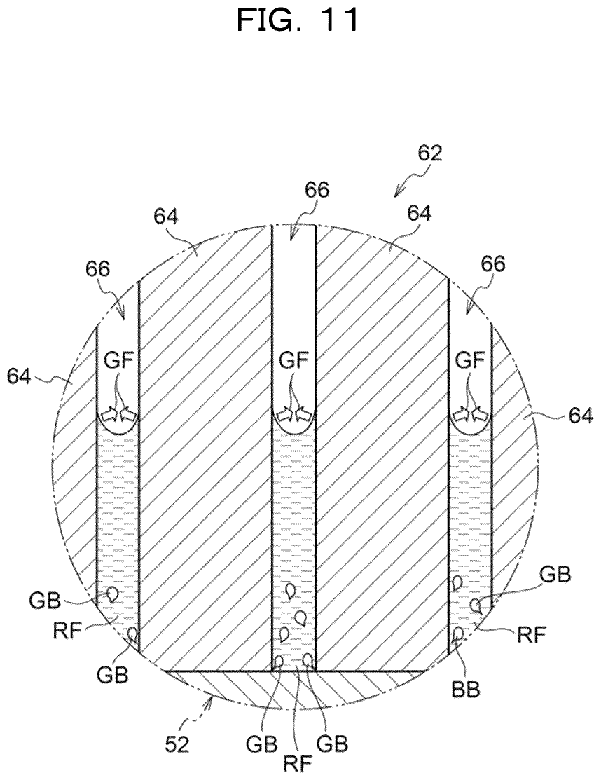

As illustrated in FIG. 11, in the groove 66, vaporization of the liquid-phase refrigerant RF is promoted by heat from the heat receiving unit 46. This “vaporization” includes “evaporation” in which the refrigerant RF vaporizes from a surface of the refrigerant RF as indicated by arrows GF, as well as “boiling” in which the refrigerant RF vaporizes from the inside of the refrigerant RF as indicated by bubbles GB. Hereinafter, both of these will be collectively expressed as “evaporation”. A portion where the column members 64 are provided is a portion where the liquid-phase refrigerant RF evaporates in this manner and is the evaporation unit 62.

Tips of the column members 64 are in contact with the top plate 54. This also ensures that, in the low pressure state inside the container 44, the interval between the top plate 54 and the bottom plate 52 is maintained, and additionally, the internal volume of the container 44 is secured.

As illustrated in FIG. 4, the heat receiving unit 46 has a diffusion space 68. The diffusion space 68 is formed between the top plate 54 and the bottom plate 52 around the heat receiving plate 60. The gas-phase refrigerant RF evaporated in the evaporation unit 62 diffuses into the diffusion space 68.

The first transport space 74 is formed between the top plate 54 and the bottom plate 52 between the heat receiving unit 46 and the heat radiating unit 48. The first transport space 74 is a space in which the gas-phase refrigerant RF produced in the evaporation unit 62 and diffused into the diffusion space 68 is transported to the heat radiating unit 48. During movement of the gas-phase refrigerant RF passing through the first transport space 74, heat of the refrigerant RF is discharged to the outside of the container 44. This condenses and liquefies the gas-phase refrigerant RF. For example, the first transport unit 50 is also a portion where the gas-phase refrigerant RF is condensed in this manner.

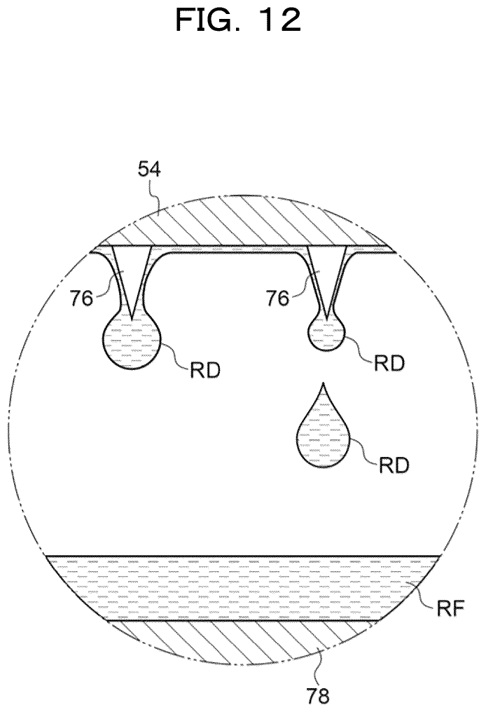

As illustrated in FIG. 12, a plurality of protrusions 76 is formed on the top plate 54 toward the bottom plate 52. Each of the protrusions 76 has a shape tapering toward a tip end side. By providing such protrusions 76, as compared with a structure without the protrusions 76, the surface area of a top surface in the condensation unit 72 is large.

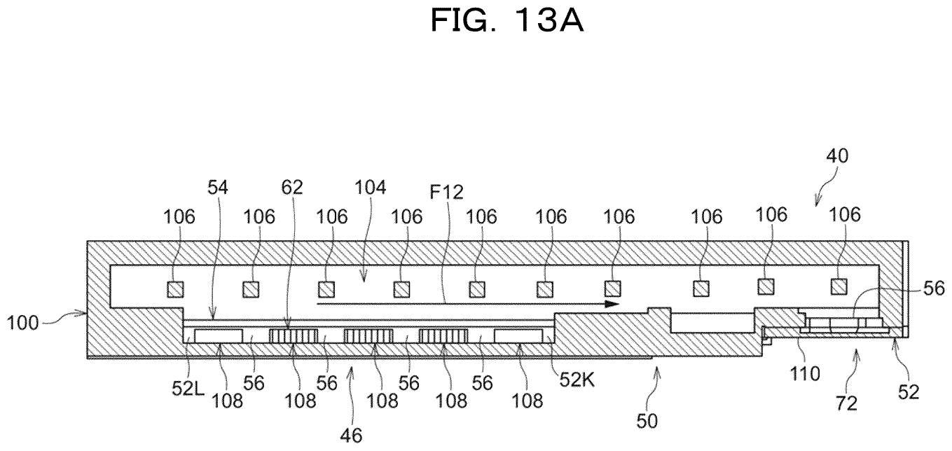

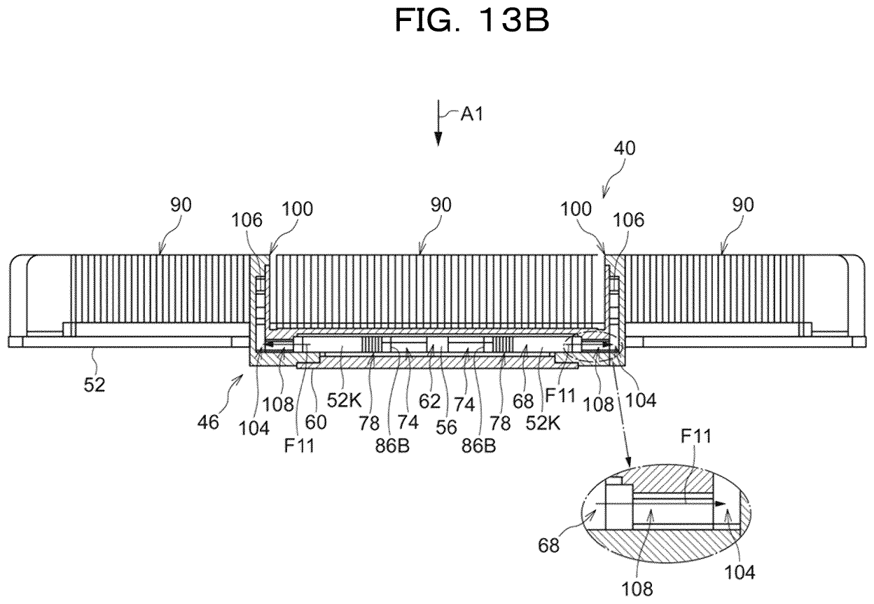

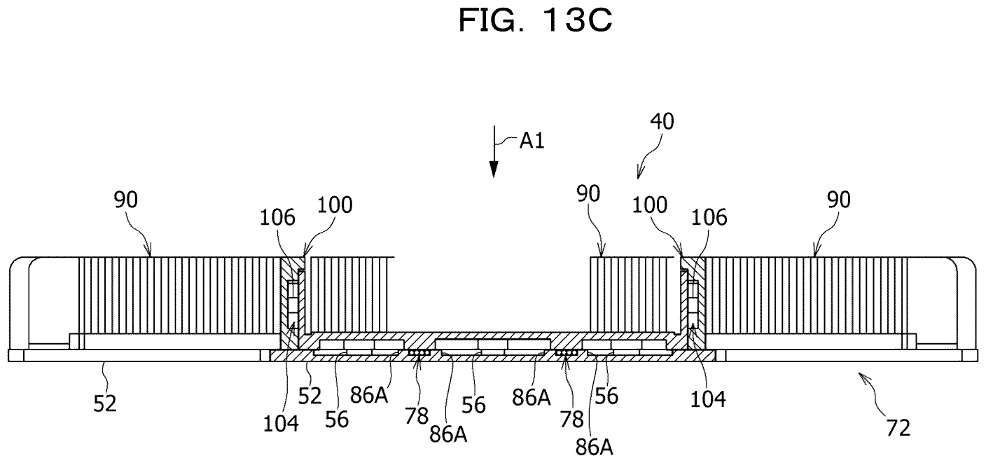

As illustrated in FIGS. 4 to 6, the transport pipe 78 extending in the depth direction is disposed inside the container 44. The number of the transport pipes 78 may be one, but a plurality of transport pipes 78 is adopted in the present embodiment. For example, in the example illustrated in FIGS. 13A to 13C, two sets of four transport pipes 78 disposed adjacent to each other in the width direction are disposed with intervals interposed therebetween in the width direction, and a total of eight transport pipes 78 are disposed. A longitudinal direction of the transport pipes 78 coincides with the depth direction of the container 44 (direction of arrow D).

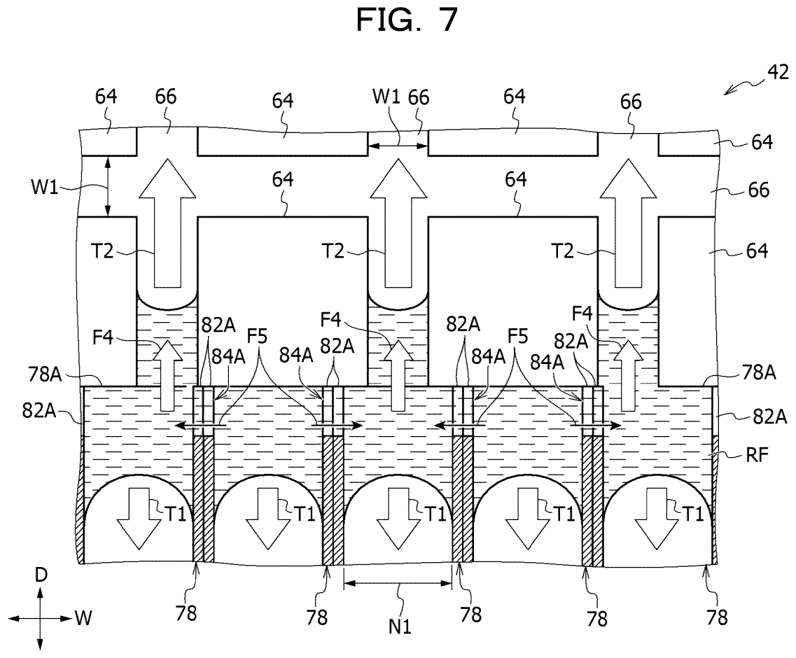

As illustrated in FIG. 7, the inner diameter N1 of the transport pipe 78 is set to a diameter that allows the liquid-phase refrigerant RF to be transported by a capillary phenomenon and allows a sufficient amount of the refrigerant RF to be transported to the evaporation unit 62 from the condensation unit 72 by the whole of the plurality of transport pipes 78. The transport pipe 78 is an example of a liquid transporter that transports the liquid-phase refrigerant RF to the evaporation unit 62 by the capillary phenomenon.

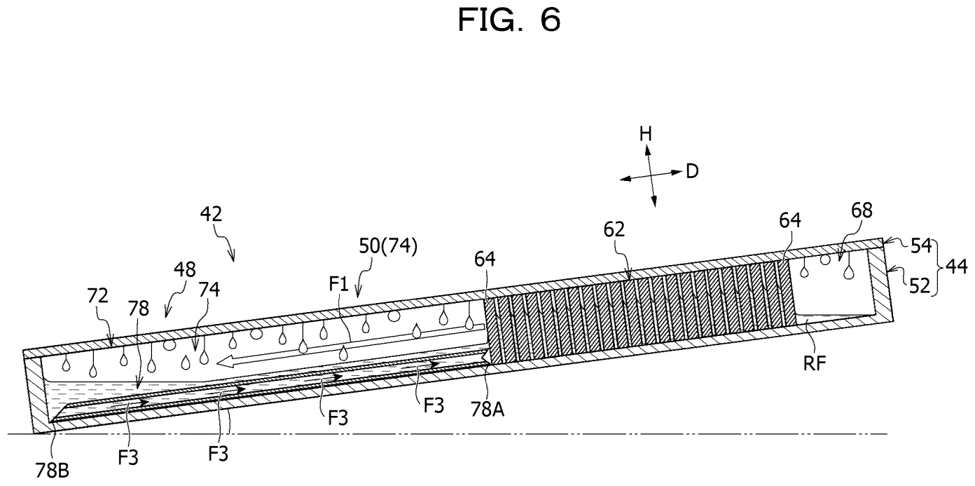

FIG. 6 illustrates a case where the cooling system 42 is inclined such that one end portion 78A is higher than another end portion 78B. An upper limit of the inner diameter N1 of the transport pipe 78 is determined such that, even in a case where the cooling system 42 is inclined in this manner, the refrigerant RF can be transported to the one end portion 78A from the another end portion 78B by the capillary phenomenon.

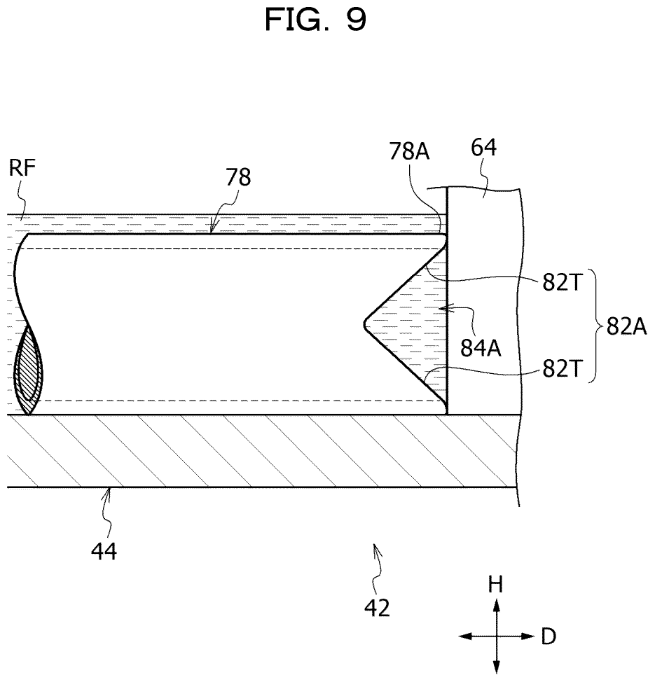

The one end portions 78A of the transport pipes 78 face the column members 64, as also illustrated in FIGS. 7 and 9. A gap portion is provided at the one end portion 78A. For example, by cutting out the transport pipe 78 at the one end portion 78A, an inclined portion 82A inclined relative to the longitudinal direction of the transport pipe 78 is formed. The inclined portion 82A is an example of the gap portion.

For example, in the present embodiment, as illustrated in FIG. 9, the inclined portion 82A has a V-shape. For example, the inclined portion 82A has inclined surfaces 82T formed in pairs so as to approach each other as being away from the column member 64. A portion where the inclined portion 82A is provided, which is a region between the inclined surfaces 82T, is a gap 84A in which the liquid-phase refrigerant RF moves to the evaporation unit 62 from the transport pipe 78. A plurality of the inclined portions 82A is formed for one transport pipe 78 with regular intervals interposed therebetween in a circumferential direction. In the present embodiment, as illustrated in FIG. 7, two inclined portions 82A are formed in one transport pipe 78 so as to be away from each other in the width direction of the container 44 (direction of arrow W).

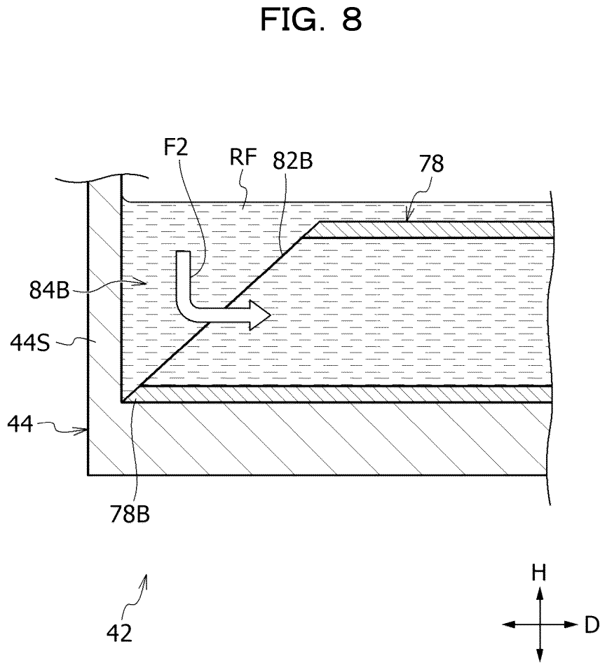

The another end portion 78B of the transport pipe 78 faces a side wall 44S of the container 44, as illustrated in FIG. 8. The side wall 44S is a side wall forming an end portion on a front side in the depth direction (a side of the condensation unit 72). A second gap portion is provided in the another end portion 78B. For example, a second inclined portion 82B obtained by inclining the another end portion 78B in one direction relative to the longitudinal direction of the transport pipe 78 is formed. A region between the side wall 44S and the second inclined portion 82B is a second gap 84B. In the second gap 84B, the liquid-phase refrigerant RF moves into the transport pipe 78 from the condensation unit 72.

As also illustrated in FIGS. 4, 13B, and 13C, projections 86A and 86B are formed inside the container 44. The projections 86A and 86B project toward the top plate 54 from the bottom plate 52. The projections 86A are located on two sides of each set of the transport pipes 78 in the width direction. The movement of the transport pipes 78 in the width direction is suppressed by the projections 86A, and the transport pipes 78 are held. The projections 86B are at positions sandwiching each set of the transport pipes 78 with the standing wall 52K. The movement of the transport pipes 78 in the width direction is also suppressed by the projections 86B and the standing wall 52K, and the transport pipes 78 are held.

The container 44 is provided with a side wall 100. In the present embodiment, there are two side walls 100. Both of the two side walls 100 are parallel to the fins 90. Each of the side walls 100 has a plate shape. The side walls 100 are each formed upward from an end portion of the heat receiving unit 46 in the width direction. The side wall 100 partially overlaps the heat receiving unit 46 in plan view, for example, when viewed in the direction of arrow μl. The side walls 100 are provided in pairs on two sides in a direction orthogonal to a moving direction of the refrigerant in the first transport unit 50 inside the container 44.

Each side wall 100 is continuous in the depth direction from an end portion on a front side to an end portion on a back side of the top plate 54. The height of the side wall 100 is about the same as the height of the fin 90. The thickness of the side wall 100 is thicker than the thickness of the fins 90. For example, while the thickness of the fin 90 is 0.2 mm or more but 0.4 mm or less, the thickness of the side wall 100 is 4 mm or more but 5 mm or less. The side wall 100 is an example of a second transporter.

As illustrated in FIGS. 13A to 13C, the side walls 100 extend in the depth direction. The side wall 100 includes a first side plate 102A and a second side plate 102B parallel to each other. A second transport space 104 is provided inside the side wall 100. As illustrated in FIG. 13A, the second transport space 104 is continuous in the depth direction from the position of the heat receiving unit 46 to the position of the heat radiating unit 48. A width (an inner dimension in the direction of arrow W) of the second transport space 104 is, for example, about 2 mm.

As illustrated in FIG. 13B, the second transport space 104 is connected to communication paths 108 at the position of the heat receiving unit 46. For example, the evaporation unit 62 and the second transport space 104 communicate with each other via the communication paths 108. This allows the fluid to move to the second transport space 104 from the evaporation unit 62.

As illustrated in FIG. 13C, the second transport space 104 communicates with the inside of the container 44 at the position of the condensation unit 72. This allows the fluid to move to the condensation unit 72 from the second transport space 104.

A plurality of support columns 106 is provided inside the side wall 100. Each support column 106 extends in a lateral direction (width direction) in the second transport space 104. One end of the support column 106 is in contact with the first side plate 102A of the side wall 100, and another end is in contact with the second side plate 102B. The second transport space 104 is maintained in a low pressure state similarly to the inside of the container 44, but even in the low pressure state, the support columns 106 maintain the interval between the first side plate 102A and the second side plate 102B. By maintaining the interval between the first side plate 102A and the second side plate 102B, the volume of the second transport space 104 is secured.

In the present embodiment, as illustrated in FIG. 13A, a plurality of the second support columns 56 is disposed with intervals interposed therebetween in the depth direction in the second transport space 104.

The side wall 100 has an action of radiating heat from the gas-phase refrigerant RF. For example, in the side wall 100, a part of heat of the gas-phase refrigerant RF inside the second transport space 104 is discharged to the outside, and the gas-phase refrigerant RF is liquefied.

In the inside of the container 44, a plurality of the second support columns 56 is provided also in a portion of the heat receiving unit 46 on two sides of the evaporation unit 62 in the width direction. A plurality of the second support columns 56 is disposed with intervals interposed therebetween in the depth direction on each of the two sides of the evaporation unit 62. On the two sides of the evaporation unit 62, the second support columns 56 maintain the interval between the top plate 54 and the bottom plate 52. Then, this secures the volume of the diffusion space 68. A region between the second support columns 56 and a region between the second support columns 56 and the standing walls 52K and 52L form the communication paths 108 for the gas-phase refrigerant RF occurring in the evaporation unit 62 to move to the second transport space 104.

As illustrated in FIG. 13A, a recess 110 is formed in the bottom plate 52 of the container 44. The recess 110 is formed at a position avoiding an electronic component mounted on the substrate 34. Since the recess 110 is formed, the container 44 has a structure that does not interfere with the electronic component. In the example illustrated in FIG. 13A, the recess 110 is formed in the bottom plate 52 at a position corresponding to the condensation unit 72, but the position of the recess 110 is not limited as long as the position can ensure to avoid the electronic component. In the cooling device 40 of the first embodiment, the recess 110 is formed by partially thinning the bottom plate 52.

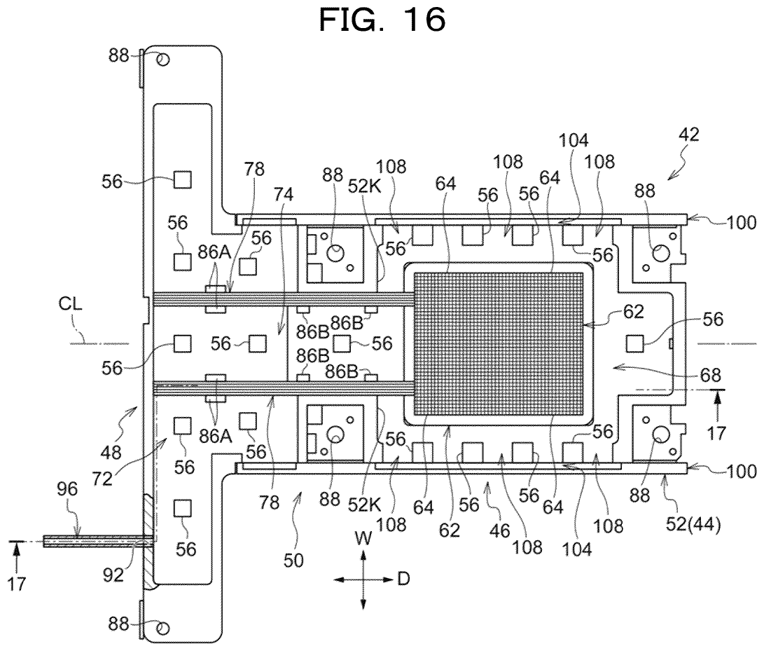

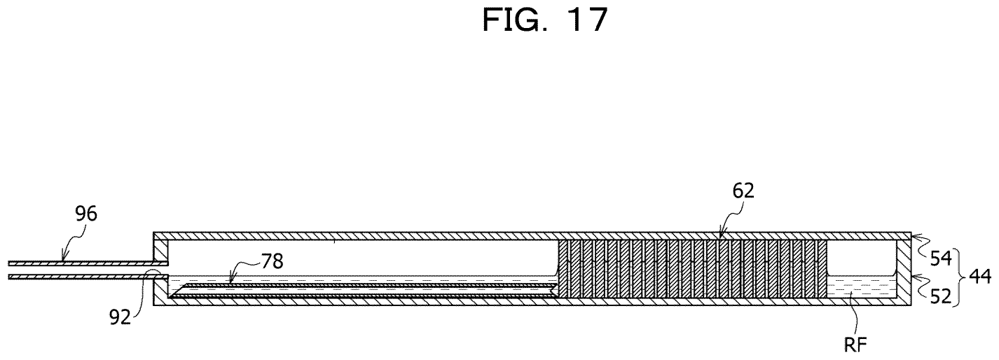

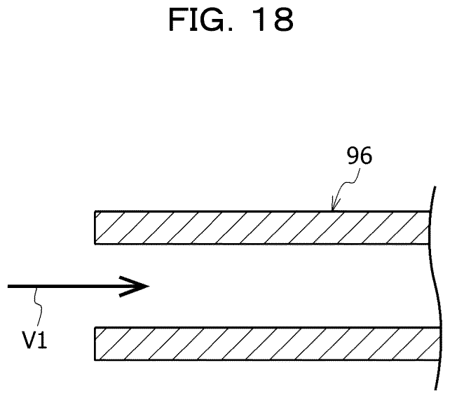

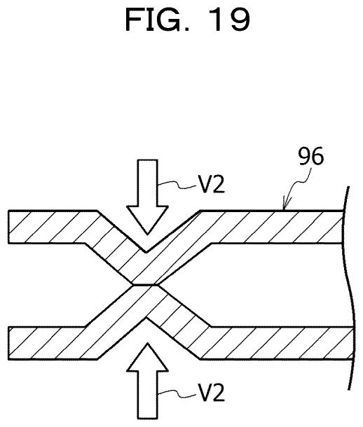

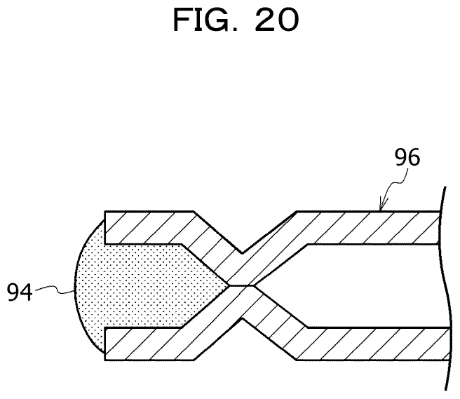

As illustrated in FIGS. 16 and 17, the container 44 is provided with an injection hole 92 that communicates the inside and the outside of the container 44. An injection pipe 96 stretches out from the injection hole 92 to the outside of the container 44. To inject the refrigerant RF into the container 44, air inside the container 44 is discharged using a vacuum pump or the like, as in FIG. 18. Thereafter, as indicated by arrow V1, the refrigerant is injected through the injection pipe 96. Then, the refrigerant inside the container 44 is heated and boiled, and dissolved air inside the refrigerant RF is discharged to the outside of the container 44. Note that this work is not involved in a case of using a degassed refrigerant from which dissolved air has been removed in advance. Next, as indicated by arrows V2 in FIG. 19, the injection pipe 96 is compressed from the outside and sealed. Furthermore, as illustrated in FIG. 20, the injection pipe 96 is more tightly sealed by filling a tip of the injection pipe 96 with a plug 94. For example, since the injection hole 92 is provided, the refrigerant RF can be injected into the inside of the container 44 through the injection hole 92. Then, after the injection, the injection hole 92 is sealed with the plug 94, whereby the refrigerant RF can be sealed inside the container 44. Note that, in the drawings other than FIGS. 16 to 20, the injection hole 92, the plug 94, and the injection pipe 96 are not illustrated.

Next, actions of the present embodiment will be described.

When the heat receiving unit 46 receives heat from the element 36, the heat vaporizes the liquid-phase refrigerant RF in the grooves 66 in the evaporation unit 62, as illustrated in FIG. 5. For example, the liquid-phase refrigerant RF turns into a gas phase due to evaporation from a surface of the refrigerant RF (see arrows GF) and boiling from the inside of the refrigerant RF (see bubbles GB).

The gas-phase refrigerant RF is diffused into the diffusion space 68. A part of the gas-phase refrigerant RF diffused into the diffusion space 68 flows into the first transport space 74. The gas-phase refrigerant RF that has flowed into the first transport space 74 moves to the condensation unit 72 through the first transport space 74 (see arrows F1 in FIGS. 5 and 6).

Furthermore, in the gas-phase refrigerant RF diffused into the diffusion space 68, a part of the gas-phase refrigerant RF that does not flow into the first transport space 74 flows into the second transport space 104 by way of the communication paths 108 as indicated by arrow F11 in FIG. 13B. Furthermore, the gas-phase refrigerant RF flowing into the second transport space 104 moves to the condensation unit 72 through the second transport space 104 as indicated by arrow F12 in FIG. 13A.

In the diffusion space 68 and the first transport space 74, a part of the gas-phase refrigerant RF is condensed and liquefied by heat radiation through the fins 90. Also in the second transport space 104, a part of the gas-phase refrigerant RF is condensed and liquefied by heat radiation through the side wall 100.

The refrigerant RF that has not been liquefied in the diffusion space 68, the first transport space 74, and the second transport space 104 reaches the condensation unit 72 while maintaining a gas phase state. In the condensation unit 72, the gas-phase refrigerant RF is condensed and liquefied. By liquefying the gas-phase refrigerant RF, heat of condensation is released from the top plate 54 to the outside of the container 44. As a result, heat of the element 36 is discharged into the outside air.

As illustrated in FIG. 4, the condensation unit 72 is formed wider in the width direction (direction of arrow W) than the evaporation unit 62. Therefore, as compared with a structure in which the condensation unit 72 is not wide in this manner, a large area for heat radiation from the gas-phase refrigerant RF may be secured, and condensation of the refrigerant RF may be promoted. The condensation unit 72 is more away from the heat receiving unit 46 than the first transport unit 50. For example, the gas-phase refrigerant RF may be transported to and condensed in not only the first transport unit 50 relatively close to the heat receiving unit 46 but also the condensation unit 72 relatively far from the heat receiving unit 46.

The fins 90 acting as the heat radiating unit 48 are disposed in the top plate 54 from a portion corresponding to the heat receiving unit 46 to a portion corresponding to the first transport unit 50 and the condensation unit 72. Heat may be radiated in a wide range of the top plate 54 to condense the gas-phase refrigerant RF.

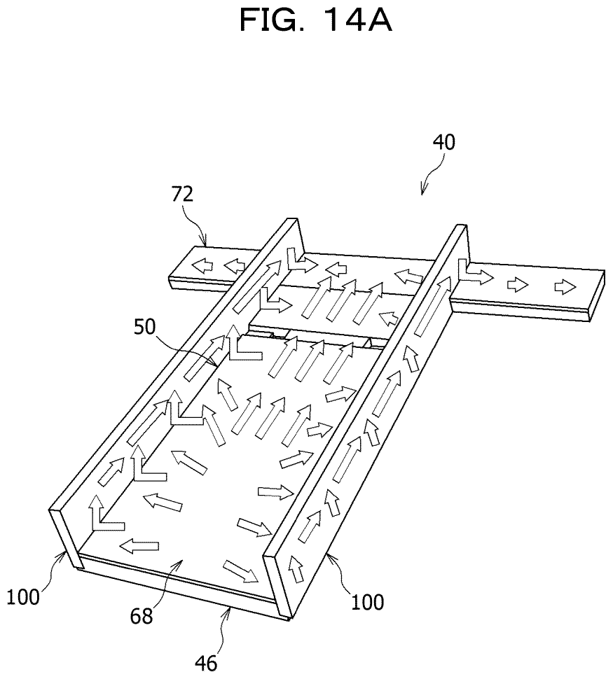

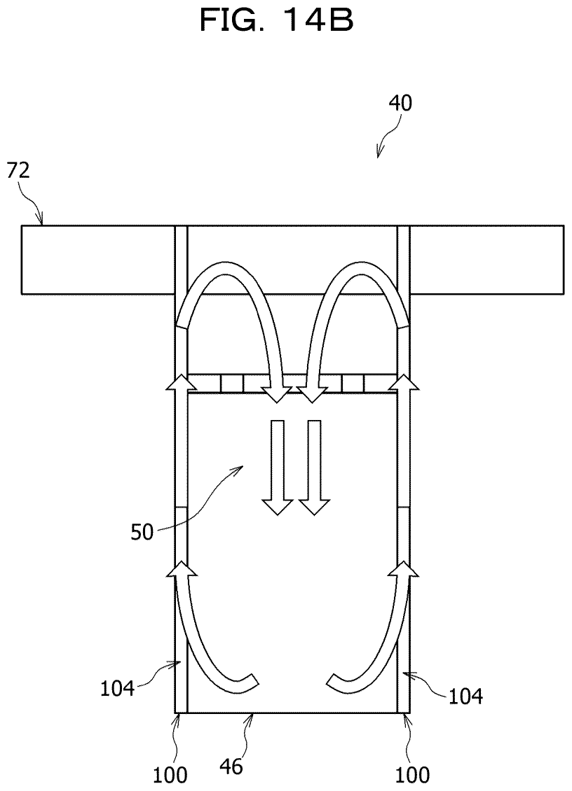

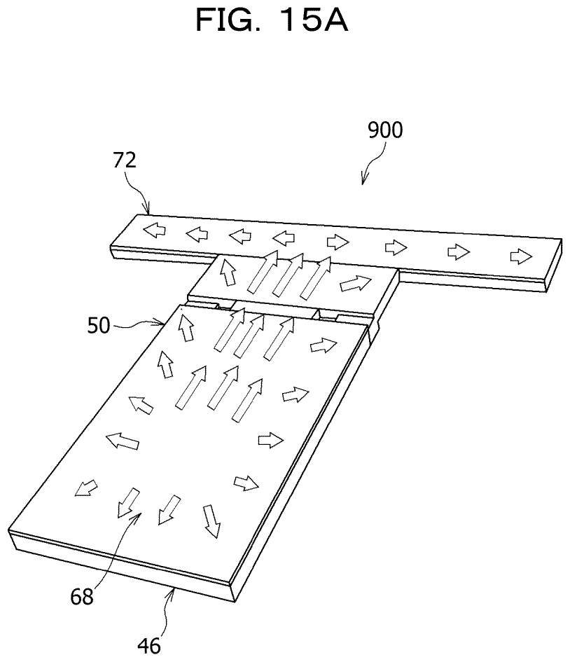

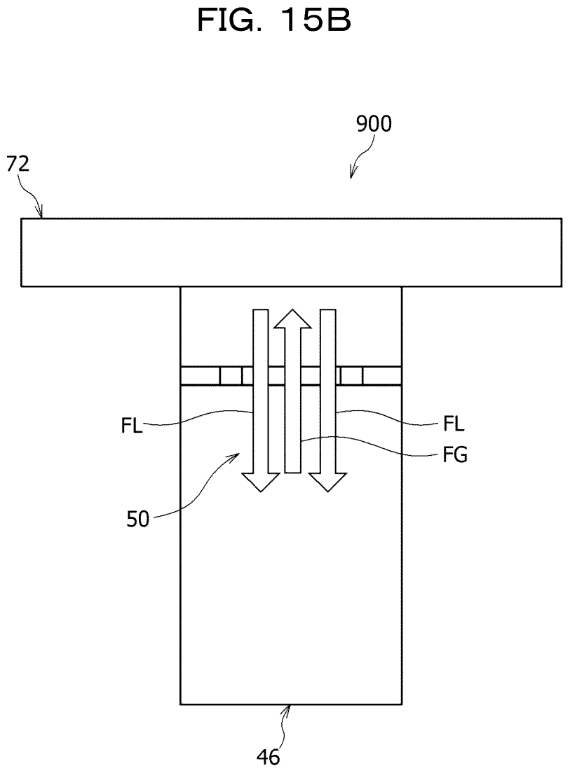

FIG. 14A illustrates flows of the gas-phase refrigerant RF in the cooling device 40 of the first embodiment. FIG. 14B illustrates flows of the gas-phase refrigerant RF and the liquid-phase refrigerant RF in the cooling device 40 of the first embodiment. FIG. 15A illustrates flows of the gas-phase refrigerant RF in a cooling device 900 of a comparative example. FIG. 15B illustrates flows of the gas-phase refrigerant RF and the liquid-phase refrigerant RF in the cooling device 900 of the comparative example.

The cooling device 900 of the comparative example has a structure without the side walls 100 as compared with the cooling device 40 of the first embodiment. Since there is no side wall 100 in the cooling device 900 of the comparative example, the cooling device 900 also does not include the second transport space 104. In the cooling device 900 of the comparative example, since there is no second transport space 104, the transport space for the refrigerant RF between the heat receiving unit 46 and the condensation unit 72 has two systems of the transport pipes 78 and the first transport space 74 (see FIG. 4 illustrated as the first embodiment). Therefore, as indicated by arrow FG in FIG. 15B, the gas-phase refrigerant RF diffused in the diffusion space 68 is transported to the condensation unit 72 only by the first transport space 74. In addition, as indicated by arrows FL in FIG. 15B, in the cooling device 900 of the comparative example, the liquid-phase refrigerant RF condensed by the condensation unit 72 is transported to the heat receiving unit 46 by the transport pipes 78. For example, in the first transport unit 50, a flow of the gas-phase refrigerant RF (arrow FG) and flows of the liquid-phase refrigerant RF (arrows FL) in a direction against the flow direction of the gas-phase refrigerant RF occur.

On the other hand, the cooling device 40 of the first embodiment has the side walls 100. The second transport space 104 is provided inside the side wall 100. As illustrated in FIG. 14A, the gas-phase refrigerant RF diffused in the diffusion space 68 is transported to the condensation unit 72 not only by the first transport space 74 but also by the second transport spaces 104 by way of the communication paths 108 (see FIG. 13B). In addition, also in the cooling device 40 of the first embodiment, the liquid-phase refrigerant RF in the condensation unit 72 is transported to the heat receiving unit 46 by the transport pipes 78. This forms loop-shaped transport paths as illustrated in FIG. 14B. In the loop-shaped transport path, the gas-phase refrigerant RF in the diffusion space 68 is transported to the condensation unit 72 by the second transport space 104 by way of the communication paths 108, and furthermore, the liquid-phase refrigerant RF is transported to the heat receiving unit 46 from the condensation unit 72 by the transport pipes 78.

Note that, in the cooling device 900 of the comparative example, in a case where such a loop-shaped transport path is formed as a transport path of the refrigerant RF, for example, it is conceivable to dispose a new member forming the transport path outside the heat receiving unit 46 and the first transport unit 50 in the width direction.

However, as illustrated in FIG. 3, in the electronic appliance 32, various elements such as the elements 38 and various components are mounted around the cooling system 42. Therefore, for example, it is difficult to planarly spread and form a coupling member coupling the heat receiving unit 46 and the condensation unit 72, such as the first transport unit 50, with respect to the cooling device 900 of the comparative example. In addition, if such a coupling member is partially bent or trimmed in order to avoid interference with various elements and various components, it is disadvantageous in terms of transporting the gas-phase refrigerant RF.

On the other hand, in the cooling device 40 of the first embodiment, the side walls 100 are provided in pairs on two sides of the first transport unit 50 inside the container 44 in a direction orthogonal to the moving direction of the refrigerant. The second transport space 104 forming a part of the loop-shaped transport path illustrated in FIG. 14B is provided without widening the container 44 in the width direction. For example, in the cooling device 40 of the first embodiment, circulation of the refrigerant RF may be promoted by forming the loop-shaped transport path in a space-saving manner. Then, by promoting the circulation of the refrigerant RF, the cooling efficiency of the cooling device 40 and the cooling system 42 may be enhanced.

In addition, the height of the electronic appliance 32 is often limited. For example, in a case where the electronic appliance 32 is a so-called rack mount server, the rack mount server is limited to a predetermined height. In this manner, even in a case where the height of the electronic appliance 32 is limited, circulation of the refrigerant RF may be promoted without increasing the height of the cooling device 40, and the cooling efficiency may be enhanced as the cooling device 40 and the cooling system 42.

The insertion holes 88 are formed in the container 44 at a position of the first transport unit 50. Then, in a portion where the insertion holes 88 are formed, the width of the first transport unit 50 is partially narrowed as compared with the structure without the insertion holes 88. Since the width of the first transport unit 50 is narrow, it is difficult to secure a wide first transport space 74 in the first transport unit 50, in addition to the transport pipes 78. To cope with this, the cooling device 40 of the first embodiment has the second transport spaces 104. Accordingly, a wide cross-sectional area of the space in which the gas-phase refrigerant RF is transported to the condensation unit 72 from the heat receiving unit 46 may be secured with the first transport space 74 and the second transport spaces 104.

In the cooling device 40 of the first embodiment, the two side walls 100 as an example of the second transporter are provided on two sides of the first transport unit 50 in the width direction (a direction orthogonal to the moving direction of the refrigerant RF). Even with one side wall 100, the movement of the gas-phase refrigerant RF from the heat receiving unit 46 to the condensation unit 72 can be promoted, but with two side walls 100, the movement of the refrigerant RF may be further promoted. Note that the number of the side walls 100 may be three or more, but in a case where there are three or more side walls 100, the side wall 100 will be provided instead of a part of the fins 90. Adopting the two side walls 100 may enable to achieve a structure that secures the number of the fins 90 while securing the cross-sectional area for the gas-phase refrigerant RF to move to the condensation unit 72 from the heat receiving unit 46 and maintains also the heat radiation capacity of the fins 90.

In a case where two side walls 100 are provided, as also illustrated in FIG. 4, the side walls 100 are provided in pairs in the width direction, for example, at symmetrical positions relative to a center line CL in the width direction. This may generate movement of the gas-phase refrigerant RF from the heat receiving unit 46 to the condensation unit 72 symmetrically relative to the center line CL in the width direction and may suppress the deviation of movement of the refrigerant RF.

In the present embodiment, the container 44 has a plate shape. For example, the first transport unit 50 has a plate shape. Then, the side wall 100 also has a plate shape and is disposed perpendicular to the first transport unit 50. The disclosed technique does not exclude an example in which the side wall 100 is disposed to be inclined to, for example, the outside in the width direction or the inside in the width direction of the container 44 relative to the first transport unit 50. When the side wall 100 is perpendicular to the first transport unit 50, a structure may be achieved in which the side wall 100 does not go out of the container 44 in the width direction in plan view or enter a region for forming the fins 90, as compared with a structure in which the side wall 100 is disposed to be inclined.

Note that the second transporter of the disclosed technique is not limited to the side wall 100. For example, in one structure, the heat receiving unit 46 and the condensation unit 72 may be coupled using one or a plurality of tubes having a cross-sectional area sufficient for transporting the gas-phase refrigerant RF. For example, even with such a structure using a tube, the tube can be restrained from going out of the container 44 in the width direction from a portion corresponding to the heat receiving unit 46 in plan view. In a case of using a plurality of tubes, if the tubes are arranged in a height direction of the container 44, a space for placing the tubes can be a narrow space.

The cooling device 40 includes the heat radiating unit 48. By radiating heat by the heat radiating unit 48, the gas-phase refrigerant RF can be condensed and liquefied inside the container 44.

The heat radiating unit 48 includes a plurality of fins 90. The plurality of fins 90 has plate shapes, which are parallel to each other. Since the fins 90 increase the area where the cooling system 42 radiates heat to the outside, heat radiation from the container 44 may be promoted as compared with a structure without the fins 90. As the heat radiation from the container 44 is promoted, the gas-phase refrigerant RF may be efficiently condensed and liquefied, and the cooling performance as the cooling system 42 may be enhanced.

The side wall 100 is parallel to the plurality of fins 90. Therefore, the side wall 100 does not disturb setting of the positions of the fins 90. Since wind from the fan also flows to two sides of the side wall 100 in the thickness direction, heat may be efficiently radiated from the side wall 100.

In both of the two side walls 100, for example, a portion corresponding to the heat receiving unit 46 is located at an end portion in an arrangement direction of the plurality of fins 90. This ensures that, in a case where an external force acts on the fins 90 in a portion corresponding to the heat receiving unit 46 from the outside in the width direction (direction of arrow W) of the container 44, the external force is received by the side walls 100. Since the external force does not act on the fins 90 by receiving the external force with the side walls 100, deformation of the fins 90 may be suppressed. Moreover, both of the two side walls 100 are thicker than the plurality of fins 90. Therefore, the side wall 100 itself is hardly deformed by the external force acting from the outside of the container 44 in the width direction.

As illustrated in FIGS. 13A and 13B, the support columns 106 are provided inside the side wall 100. The support columns 106 may suppress approach between the first side plate 102A and the second side plate 102B and maintain the volume of the second transport space 104. For example, a cross-sectional area for the gas-phase refrigerant RF to flow may be maintained.

For example, since a plurality of the support columns 106 is provided for one second transport space 104, the volume of the second transport space 104 may be easily maintained as compared with a structure in which there is one support column 106. The plurality of the support columns 106 is disposed with intervals interposed therebetween in the depth direction. Accordingly, as compared with a structure in which the plurality of the support columns 106 is closely disposed without intervals interposed therebetween, the interval between the first side plate 102A and the second side plate 102B may be maintained without excessively narrowing the volume of the second transport space 104.

The diffusion space 68 is provided inside the container 44. In the diffusion space 68, the gas-phase refrigerant RF produced in the evaporation unit 62 can be diffused around the evaporation unit 62.

Inside the container 44, the second support columns 56 are provided between the top plate 54 and the bottom plate 52 at a position of the diffusion space 68. Since the interval between the top plate 54 and the bottom plate 52 can be maintained by the second support columns 56, a volume for diffusing the gas-phase refrigerant RF around the evaporation unit 62 may be secured inside the container 44, as the diffusion space 68. For example, the inside of the container 44 is maintained at a low pressure as compared with an atmospheric pressure in order to promote vaporization of the liquid-phase refrigerant RF. In this case, a force in an approaching direction acts on the top plate 54 and the bottom plate 52 due to the pressure difference between a pressure inside the container 44 (a vapor pressure of the gas-phase refrigerant RF) and the atmospheric pressure. Even in a case where such a force acts, the approach between the top plate 54 and the bottom plate 52 may be suppressed. For example, since the interval between the top plate 54 and the bottom plate 52 can be maintained, the volume of the diffusion space 68 may be maintained.

For example, a plurality of the second support columns 56 is provided on two sides of the evaporation unit 62 in the width direction. Therefore, it is easy to secure the volume of the diffusion space 68 as compared with a structure in which only one second support column 56 is provided on each of two sides of the evaporation unit 62 in the width direction. The plurality of the second support columns 56 is disposed with intervals interposed therebetween in the depth direction, and the communication paths 108 are formed between the second support columns 56. The gas-phase refrigerant RF produced in the evaporation unit 62 smoothly moves to the second transport space 104 through the communication paths 108.

Note that, in one structure, the second support column 56 may be provided on the top plate 54, and a lower end of the second support column 56 may be in contact with the bottom plate 52, or in another structure, the second support column 56 may be separate from both of the top plate 54 and the bottom plate 52, an upper end may be in contact with the top plate 54, and a lower end may be in contact with the bottom plate 52, respectively.

In the inside of the container 44, the liquid-phase refrigerant RF comes into the transport pipe 78 from the another end portion 78B of the transport pipe 78, as indicated by arrow F2 in FIG. 8. Furthermore, the refrigerant RF is transported to the one end portion 78A, which is, toward the evaporation unit 62 by the capillary phenomenon, as indicated by arrows F3 in FIGS. 5 and 6.

In the evaporation unit 62, the liquid-phase refrigerant RF is evaporated and vaporized again in the grooves 66. In this manner, inside the container 44, the refrigerant RF is circulated between the evaporation unit 62 and the condensation unit 72 while repeating the phase transition between the liquid phase and the gas phase, whereby the heat received by the heat receiving unit 46 can be conveyed to the heat radiating unit 48. This allows the element 36 that is a cooling target to be cooled.

As illustrated in FIG. 7, in the present embodiment, the groove width W1 of the groove 66 of the evaporation unit 62 is smaller than the inner diameter N1 of the transport pipe 78.

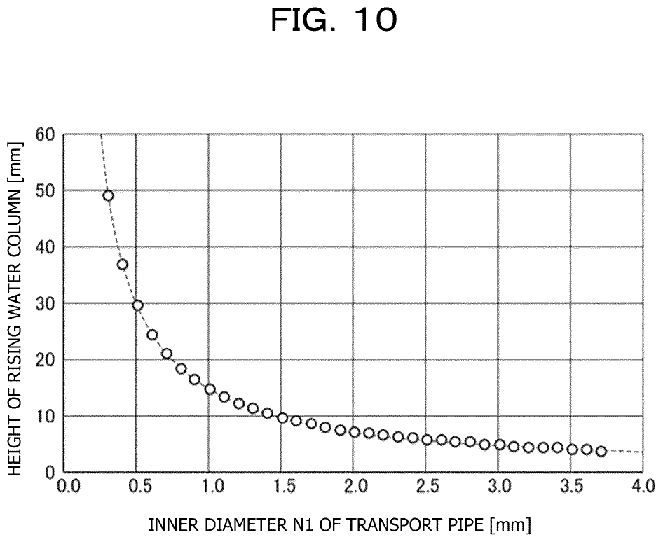

FIG. 10 illustrates a relationship between the inner diameter N1 of the transport pipe 78 and a rising height of a liquid column that rises inside the transport pipe 78 due to the surface tension (capillary phenomenon), in a case where a liquid temperature is 25° C. This graph is an example of water used as the refrigerant RF in the present embodiment.

As is known from this graph, the smaller the inner diameter N1 of the transport pipe 78, the higher the rising height of the liquid column. For example, as the inner diameter N1 is smaller, the refrigerant RF may be raised with larger surface tension.

In the transport pipe 78, as indicated by arrows F3 in FIGS. 5 and 6, the liquid-phase refrigerant RF is transported to the evaporation unit 62. However, at the one end portion 78A of the transport pipe 78, as illustrated in FIG. 7, a refrigerant RF-suction force T1 sometimes acts in a direction away from the evaporation unit 62 due to the surface tension of the liquid-phase refrigerant RF inside the transport pipe 78. On the other hand, in the evaporation unit 62, a refrigerant RF-suction force T2 for drawing the refrigerant RF into the inside of the evaporation unit 62 sometimes acts on due to the surface tension of the liquid-phase refrigerant RF in the grooves 66. The refrigerant RF-suction force T1 and the refrigerant RF-suction force T2 are forces in opposite directions, but since the refrigerant RF-suction force T2 is larger, the refrigerant RF flows toward the evaporation unit 62 from the transport pipe 78 as indicated by arrows F4.

Here, for example, as illustrated in FIG. 6, a case of using the cooling system 42 in an inclined manner such that the one end portion 78A is higher than the another end portion 78B will be considered. As an example, it is assumed that the one end portion 78A is about 25 mm higher than the another end portion 78B. In this case, it may be seen that, when the inner diameter N1 of the transport pipe 78 is set to 0.6 mm or less, the refrigerant RF can be transported inside the transport pipe 78 toward the one end portion 78A from the another end portion 78B due to the surface tension.

In this manner, from the viewpoint of increasing the surface tension acting on the refrigerant RF inside the transport pipe 78, it is sufficient that the inner diameter N1 of the transport pipe 78 is made smaller. However, when the inner diameter N1 of the transport pipe 78 is made smaller, the flow path cross-sectional area of the refrigerant RF also becomes smaller, such that the amount of the refrigerant RF that can be transported per unit time also becomes smaller. Therefore, a lower limit value of the inner diameter N1 of the transport pipe 78 is determined from the viewpoint of securing the transport amount for the refrigerant RF per unit time.

As illustrated in FIG. 7, in the present embodiment, the groove width W1 of the groove 66 is narrower than the inner diameter N1 of the transport pipe 78. From the relationship illustrated in FIG. 10, the surface tension acting on the liquid-phase refrigerant RF in the evaporation unit 62 is larger than the surface tension acting on the liquid-phase refrigerant RF in the transport pipe 78. Therefore, by a difference between the refrigerant RF-suction force T2 and the refrigerant RF-suction force T1, a force to move to the evaporation unit 62 from the transport pipe 78 is caused to act, and the refrigerant RF can be moved to the evaporation unit 62 from the transport pipe 78.

Here, a structure in which the one end portion 78A of the transport pipe 78 is formed flat without providing the gap portion will be considered. In the transport pipe having the flat one end portion 78A, when an opening portion of the transport pipe faces and is in contact with the column member 64 over an entire circumference, the opening portion is sometimes covered by the column member 64. By increasing the inner diameter N1 of the transport pipe, it is possible to secure a range that is not covered by the column member 64 at the opening portion of the transport pipe. However, in order to ensure that the surface tension described above acts on the refrigerant RF, the inner diameter N1 has an upper limit.

To cope with this, in the present embodiment, the inclined portion 82A is provided at the one end portion 78A of the transport pipe 78 as an example of the gap portion. Then, even when a tip portion of the one end portion 78A is in contact with the evaporation unit 62, the gap 84A that does not contact the evaporation unit 62 is formed between the transport pipe 78 and the evaporation unit 62. For example, the structure is such that the opening portion at the one end portion 78A of the transport pipe 78 is not completely blocked by the column member 64. Therefore, as indicated by arrows F5 in FIG. 7, the liquid-phase refrigerant RF transported by the transport pipe 78 flows into the groove 66 of the evaporation unit 62 through the gap 84A. For example, a structure that facilitates movement of the liquid phase refrigerant RF to the evaporation unit 62 from the transport pipe 78 is achieved.

In the structure in which the groove width W1 of the groove 66 is narrower than the inner diameter N1 of the transport pipe 78 as described above, the column member 64 is made relatively thick and covers a wide range of the opening portion of the transport pipe 78. However, even in such a structure, in the present embodiment, since the gap 84A is formed between the transport pipe 78 and the evaporation unit 62, the liquid-phase refrigerant RF may be reliably moved to the evaporation unit 62 from the transport pipe 78.

In the first embodiment, the gap portion is the inclined portion 82A provided at the one end portion 78A of the transport pipe 78. When the gap portion is provided in the transport pipe 78 in this manner, no other member for forming the gap 84A is involved, and the structure of the cooling system 42 may be simplified.

The gap portion is the inclined portion 82A in the example described above. For example, the gap 84A may be formed with the simple structure in which the one end portion 78A of the transport pipe 78 is inclined relative to the longitudinal direction of the transport pipe 78.

As illustrated in FIG. 9, the inclined portion 82A has the pair of inclined surfaces 82T. The inclined surfaces 82T are surfaces that approach each other as being away from the evaporation unit 62. By forming the inclined portion 82A including such inclined surfaces 82T, a structure may be achieved in which the gap 84A is formed without making the depth to cut the inclined portion 82A (the length of the portion cut from the side of the evaporation unit 62) excessively long.

Note that the one end portion 78A of the transport pipe 78 may be provided with an inclined portion inclined in one direction in a similar manner to the second inclined portion 82B of the another end portion 78B.

In addition, the inclined portion 82A as an example of the gap portion is provided at a plurality of places (two places in the present embodiment) in the circumferential direction for one transport pipe 78. Since a plurality of the gaps 84A is formed by providing the plurality of gap portions, a wide cross-sectional area of a portion where the refrigerant RF flows to the evaporation unit 62 from the transport pipe 78 may be secured as compared with that of a structure in which only one gap portion is provided for one transport pipe 78.

The another end portion 78B of the transport pipe 78 is provided with the second inclined portion 82B as an example of the second gap portion, and the second gap 84B is formed between the another end portion 78B and the side wall 44S of the container 44. For example, the structure is such that the opening portion at the another end portion 78B of the transport pipe 78 is not blocked by the side wall 44S. Therefore, a structure is achieved in which the liquid-phase refrigerant RF inside the container 44 easily flows into the inside of the transport pipe 78 through the second gap 84B.

A plurality of the transport pipes 78 as an example of the liquid transporter is provided. As described above, in terms of increasing the surface tension acting on the liquid-phase refrigerant RF flowing through the transport pipe 78, since the inner diameter N1 of the transport pipe 78 has an upper limit, it is difficult to secure a sufficient flow rate with only one transport pipe 78. To cope with this, by providing the plurality of transport pipes 78, the transport pipes 78 may secure a larger flow rate as a whole.

The plurality of transport pipes 78 is disposed such that a flow path of the liquid-phase refrigerant RF is formed also between the two adjacent transport pipes 78 and the bottom plate 52. Since not only the inside of the transport pipe 78 but also the outside of the transport pipe 78 is used as a region where the liquid-phase refrigerant RF flows, a large flow rate of the refrigerant RF may be secured as compared with a structure in which such a flow path is not formed.

The transport pipes 78 are fixed to the container 44 by the projections 86. The transport pipes 78 are not fixed to the container by so-called brazing or adhesion, and no solder or adhesive is involved. Then, since the solder or the adhesive does not melt out due to a temperature change (high temperature) or the like associated with the use of the cooling system 42, there is no influence on the phase transition of the refrigerant RF inside the container 44.

In addition, since the plurality of transport pipes 78 is fixed in contact with the bottom plate 52 by the projections 86, a sufficient flow path cross-sectional area for the gas-phase refrigerant RF to move may be substantially secured between the top plate 54 and the transport pipes 78.

The top plate 54 is provided with the protrusions 76. The gas-phase refrigerant RF flowing while contacting the top plate 54 is condensed and liquefied by heat radiation to the outside of the container 44 through the top plate 54. At this time, as illustrated in FIG. 12, the protrusions 76 increase the substantial contact area in which the refrigerant RF contacts the top plate 54, as compared with a structure without the protrusions 76. This facilitates liquefaction of the gas-phase refrigerant RF as droplets RD and may promote liquefaction of the refrigerant RF. Then, since the liquefied refrigerant RF is efficiently dropped along the protrusions 76, a liquid film may be maintained thin on the top plate 54 at a portion where the protrusions 76 are not formed. By maintaining the liquid film thin, a structure may be achieved in which heat is efficiently transferred to the top plate 54 from the gas-phase refrigerant RF, and a high condensation and liquefaction capacity for the refrigerant RF is maintained.

The container 44 is provided with the insertion holes 88. By inserting the fasteners into the insertion holes 88, a structure may be easily achieved in which the cooling system 42 is fixed to the substrate 34 and further fixed to the element 36 that is a cooling target.

The container 44 has the injection hole 92. With the injection hole 92, the refrigerant RF may be easily injected into the inside of the container 44 through the injection pipe 96. Then, by filling the injection pipe 96 with the plug 94, a structure may be achieved in which the injection hole 92 is sealed with the plug 94 and the refrigerant RF is sealed inside the container 44.

### Second Embodiment

Next, a second embodiment will be described. In the second embodiment, elements, members, and the like similar to those in the first embodiment are denoted by the same reference signs as those in the first embodiment, and detailed description thereof will be omitted. In addition, since an overall structure of a cooling system 202 of the second embodiment is similar to that of the cooling system 42 of the first embodiment, illustration thereof will be omitted.

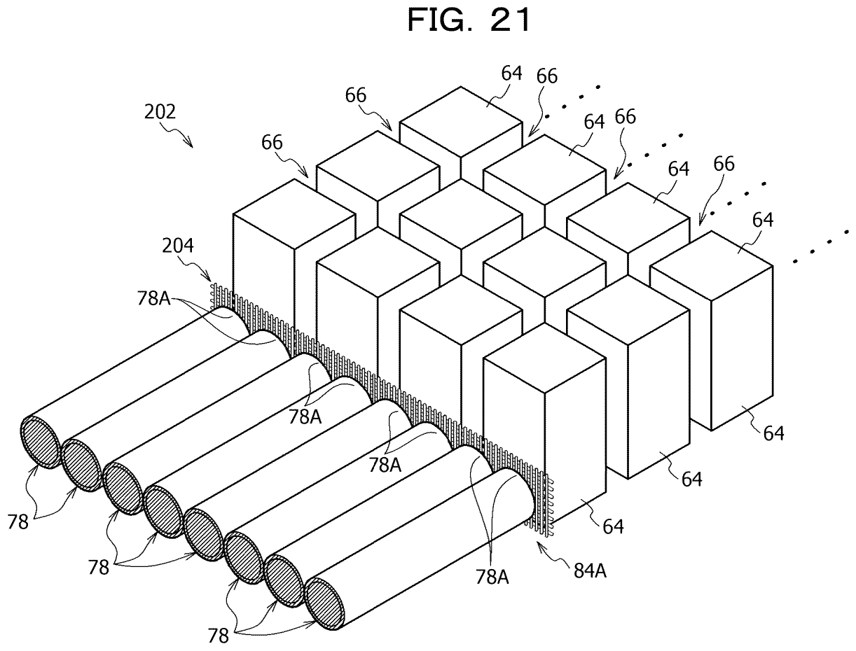

As illustrated in FIG. 21, the cooling system 202 of the second embodiment includes, as an example of the gap portion, a net member 204 separate from a transport pipe 78 and an evaporation unit 62. The net member 204 is disposed between the transport pipes 78 and the evaporation unit 62, with one surface in contact with the transport pipes 78 and another surface in contact with the evaporation unit 62. Note that, in the cooling system 202 of the second embodiment, the inclined portion 82A of the first embodiment (see FIG. 9) is not formed at a one end portion 78A of the transport pipe 78, and the one end portion 78A is orthogonal to the longitudinal direction of the transport pipe 78.

The net member 204 is a member that allows fluid to move in the thickness direction (direction of arrow T), and the net member 204 forms a gap 84A between the transport pipes 78 and the evaporation unit 62. Therefore, the one end portion 78A of the transport pipe 78 is not blocked by the evaporation unit 62, and the flow path of the refrigerant RF from the one end portion 78A toward the evaporation unit 62 is secured. For example, also in the cooling system 202 of the second embodiment, a structure that facilitates movement of the liquid-phase refrigerant RF from the transport pipe 78 to the evaporation unit 62 is achieved.

In the second embodiment, the net member 204 as an example of the gap portion is separate from the transport pipe 78 and the evaporation unit 62. Therefore, the shape of the transport pipe 78 or the evaporation unit 62 is not affected. For example, the one end portion 78A of the transport pipe 78 is no longer has to be processed, and the structure may be simplified.

The net member 204 is disposed between the transport pipe 78 and the evaporation unit 62 and is in contact with both of them. This maintains a relative position between the transport pipe 78 and the evaporation unit 62 and thus may also maintain a state in which the gap 84A is formed.

### Third Embodiment

Next, a third embodiment will be described. In the third embodiment, elements, members, and the like similar to those in the first embodiment are denoted by the same reference signs as those in the first embodiment, and detailed description thereof will be omitted. In addition, since an overall structure of a cooling system 302 of the third embodiment is similar to that of the cooling system 42 of the first embodiment, illustration thereof will be omitted.

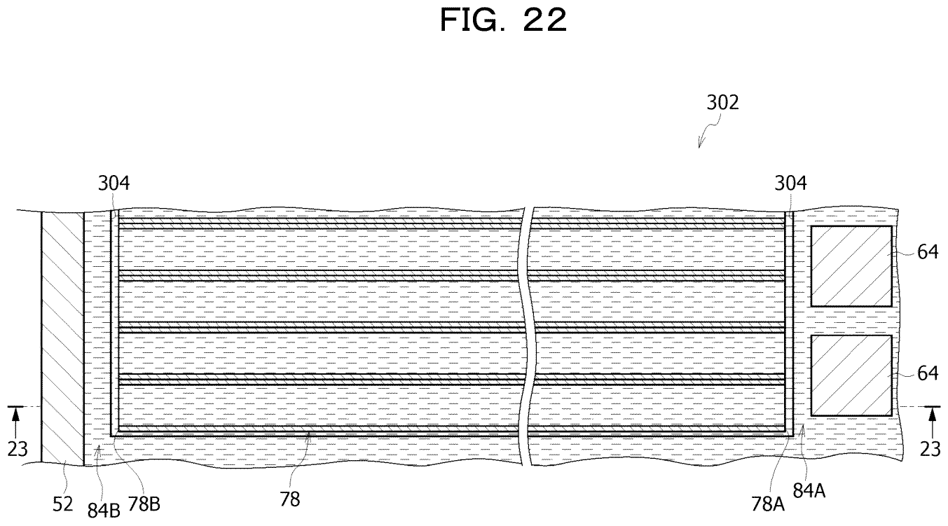

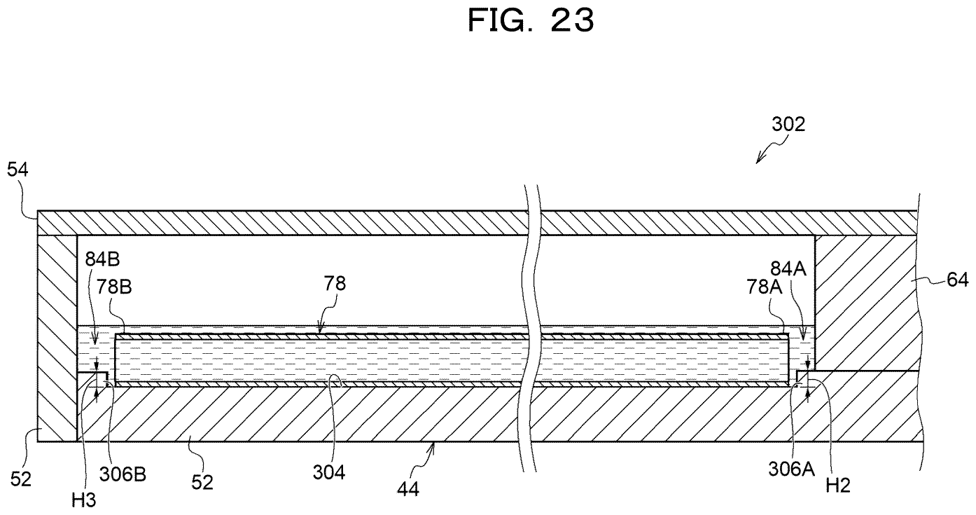

As illustrated in FIGS. 22 and 23, in the cooling system 302 of the third embodiment, a recess 304 is provided in a bottom plate 52. The recess 304 has a shape capable of accommodating a lower portion of each transport pipe 78. Then, as a part of the bottom plate 52, a wall portion 306A is provided between the recess 304 and an evaporation unit 62. In addition, as a part of the bottom plate 52, a second wall portion 306B is provided between the recess 304 and a side wall 44S of a container 44. Substantially, the wall portion 306A and the second wall portion 306B are portions of the bottom plate 52 where the recess 304 is not provided.

The wall portion 306A faces a one end portion 78A of the transport pipe 78 and is set to a height H2 that is enough not to obstruct a substantial flow of the refrigerant RF in an inner peripheral portion of the transport pipe 78. Then, the wall portion 306A forms a gap 84A between the one end portions 78A of the transport pipes 78 and an evaporation unit 62. For example, in the third embodiment, the wall portion 306A is an example of the gap portion.

In this manner, in the third embodiment, the wall portion 306A forms the gap 84A between the transport pipe 78 and the evaporation unit 62. Therefore, the one end portion 78A of the transport pipe 78 is not blocked by the evaporation unit 62, and the flow path of the refrigerant RF from the one end portion 78A toward the evaporation unit 62 is secured. For example, also in the cooling system 302 of the third embodiment, a structure that facilitates movement of the liquid-phase refrigerant RF from the transport pipe 78 to the evaporation unit 62 is achieved.

The second wall portion 306B faces another end portion 78B of the transport pipe and is set to a height H3 that is enough not to obstruct the substantial flow of the refrigerant RF in the inner peripheral portion of the transport pipe 78. Then, the second wall portion 306B forms a second gap 84B between the another end portion 78B of the transport pipe 78 and the side wall 44S of the container 44. For example, in the third embodiment, the second wall portion 306B is an example of the second gap portion. Note that, since the height H2 of the wall portion 306A and the height H3 of the second wall portion 306B both correspond to the depth of the recess 304, the height H2 of the wall portion 306A and the height H3 of the second wall portion 306B are equal to each other.

In the third embodiment, the wall portion 306A as an example of the gap portion is provided in the container 44. Since the gap portion is not provided in the transport pipe 78, the one end portion 78A of the transport pipe 78 no longer has to be processed, and the structure may be simplified. In addition, since a new member does not have to be provided as the gap portion, the number of components does not increase.

In the third embodiment, the recess 304 is provided in the container 44. As a portion facing the one end portion 78A of the transport pipe 78, a structure having the gap portion may be achieved with a simple structure.

In addition, since the transport pipe 78 is accommodated in the recess 304 of the bottom plate 52, the space between the transport pipe 78 and the top plate 54, which is a region as a movement portion, may be secured wide as compared with a structure without the recess 304.

While the embodiments of the technique disclosed in the present application have been described thus far, the technique disclosed in the present application is not limited to the embodiments described above, and it will be understood that, in addition to the embodiments described above, various modifications may be made and implemented within the spirit and scope of the technique.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A cooling device comprising:
a container in which a refrigerant is sealed;
a heat receiver configured to receive heat from a cooling target and evaporate the refrigerant inside the container;
a condenser that is disposed away from the heat receiver inside the container, and configured to condense the gas-phase refrigerant;
a liquid transporter configured to couple the condenser and the heat receiver, and transport the liquid-phase refrigerant to the heat receiver from the condenser by a capillary phenomenon;
a first transporter configured to couple the heat receiver and the condenser inside the container, and include a first transport space inside the first transporter, in which the gas-phase refrigerant is transported to the condenser from the heat receiver; and
a second transporter that is provided in pairs over two sides in a direction orthogonal to a moving direction of the refrigerant in the first transporter inside the container, and configured to couple the heat receiver and the condenser, and include a second transport space inside the second transporter, in which the gas-phase refrigerant is transported to the condenser from the heat receiver.

2. The cooling device according to claim 1, wherein the first transporter and the second transporter both have a plate shape, and the second transporter is disposed perpendicular to the first transporter.

3. The cooling device according to claim 1, further comprising:
a heat radiator configured to release heat to an outside from the container.

4. The cooling device according to claim 3, wherein the heat radiator includes a plurality of fins.

5. The cooling device according to claim 4, wherein the plurality of the fins has a plate shape and parallel to each other.

6. The cooling device according to claim 5, further comprising:
a side wall that is parallel to the plurality of the fins and configured to constitute the second transporter.

7. The cooling device according to claim 6, wherein the side wall is thicker than each of the fins.

8. The cooling device according to claim 6, further comprising:
support columns that are provided inside the side wall and configured to maintain the second transport space.

9. The cooling device according to claim 8, wherein the support columns are disposed with spaces interposed between the support columns.

10. The cooling device according to claim 1, further comprising:
second support columns that are provided inside the container and configured to maintain a diffusion space in which the evaporated refrigerant is diffused.

11. The cooling device according to claim 10, wherein the second support columns are disposed with spaces interposed between the second support columns.

12. The cooling device according to claim 1, further comprising:
an insertion hole that is provided in the container, and through which a screw configured to fix the container to a heating component is inserted.

13. A cooling system comprising:
a container in which a refrigerant is sealed;
a heat receiver configured to receive heat from a cooling target and evaporate the refrigerant inside the container;
a condenser that is disposed away from the heat receiver inside the container, and configured to condense the gas-phase refrigerant;
a liquid transporter configured to couple the condenser and the heat receiver, and transport the liquid-phase refrigerant to the heat receiver from the condenser by a capillary phenomenon;
a first transporter configured to couple the heat receiver and the condenser inside the container, and include a first transport space inside the first transporter, in which the gas-phase refrigerant is transported to the condenser from the heat receiver;
a second transporter that is provided in pairs over two sides in a direction orthogonal to a moving direction of the refrigerant in the first transporter inside the container, and configured to couple the heat receiver and the condenser, and include a second transport space inside the second transporter, in which the gas-phase refrigerant is transported to the condenser from the heat receiver; and
a heat radiator configured to release heat to an outside from the container.

14. The cooling system according to claim 13, wherein the direction from the condenser toward the heat receiver is the direction of a flow of wind by a fan.
